(19) United States
(12) Patent Application Publication
(10) Pub. No.: US 2025/0155532 A1
(43) Pub. Date: May 15, 2025

(54) MAGNETIC RESONANCE COIL, COIL ASSEMBLY, AND MAGNETIC RESONANCE DEVICE

(71) Applicant: WUHAN UNITED IMAGING LIFE SCIENCE INSTRUMENT CO., LTD, Wuhan (CN)

(72) Inventors: Chuo Xie, Wuhan (CN); Dashen Chu, Wuhan (CN)

(21) Appl. No.: 18/945,566

(22) Filed: Nov. 13, 2024

(30) Foreign Application Priority Data
Nov. 13, 2023 (CN) 202311521155.5

(51) Int. Cl. G01R 33/34; G01R 33/36

(52) U.S. Cl. CPC G01R 33/34007; G01R 33/3642

(57) ABSTRACT

A magnetic resonance coil, a coil assembly and a magnetic resonance device. The magnetic resonance coil is used for receiving a magnetic resonance signal of a to-be-scanned object, and includes a first coil group and a second coil group. The first coil group includes at least two coils arranged in a first direction, and the second coil group includes at least two coils arranged in a second direction. The first coil group and the second coil group are arranged to overlap, and each two adjacent coils in the first coil group and in the second coil group are arranged to be decoupled.

### CROSS-REFERENCE TO RELATED APPLICATION

The present application claims the priority to Chinese patent application No. 202311521155.5, filed on Nov. 13, 2023, and entitled “MAGNETIC RESONANCE COIL, COIL ASSEMBLY, AND MAGNETIC RESONANCE DEVICE”, which is incorporated herein by reference in its entirety.

### TECHNICAL FIELD

The present application relates to the field of magnetic resonance technology, and in particular to a magnetic resonance coil, a coil assembly, and a magnetic resonance device.

### BACKGROUND

Having advantages such as safe scanning and clear imaging, a magnetic resonance imaging device has been gradually used in a variety of examinations on humans or animals.

A conventional magnetic resonance device includes a coil. When the magnetic resonance device is used to scan and image a human body or an animal body to be scanned, the magnetic resonance scanning in various directions is generally performed on the to-be-scanned object by using the coil to obtain scanning signals, where the various directions include an anterior posterior (AP) direction, a right-left (RL) direction, and a head-foot (HF) direction. Finally, an image is reconstructed based on the signals obtained via scanning to obtain a magnetic resonance image.

### SUMMARY

The present application provides a magnetic resonance coil, a coil assembly, and a magnetic resonance device, which can improve an imaging efficiency when scanning a to-be-scanned object.

In a first aspect, the present application provides a magnetic resonance coil for receiving a magnetic resonance signal of a to-be-scanned object, the magnetic resonance coil includes a first coil group and a second coil group. The first coil group includes at least two coils arranged in a first direction, and the second coil group includes at least two coils arranged in a second direction. The first coil group and the second coil group are arranged to overlap, and each two adjacent coils in the first coil group and the second coil group are arranged to be decoupled.

In one of the embodiments, the first direction is perpendicular to the second direction.

In one of the embodiments, the first coil group and the second coil group are arranged to overlap in a third direction, and the third direction is perpendicular to both the first direction and the second direction.

In one of the embodiments, in the first coil group, the at least two coils arranged in the first direction includes a first loop coil and a second loop coil; the first loop coil and the second loop coil have a first overlap region.

In one of the embodiments, each two adjacent coils in the second coil group have a first space.

In one of the embodiments, in the second coil group, the at least two coils arranged in the second direction includes a third loop coil and a fourth loop coil, and the third loop coil and the fourth loop coil are connected by an electronic component, and the electronic component includes a capacitor.

In one of the embodiments, the first overlap region of the first loop coil and the second loop coil is spaced apart from the third loop coil and the fourth loop coil in the second coil group.

In one of the embodiments, the first loop coil and the third loop coil form a first overlap sub-region, and the first loop coil and the fourth loop coil form a second overlap sub-region.

A first ratio of an area of the first overlapping sub-region to an area of the first loop coil or to an area of the third loop coil is greater than or equal to 0.08, and less than or equal to 0.15.

A second ratio of an area of the second overlapping sub-region to the area of the first loop coil or an area of the fourth loop coil is greater than or equal to 0.08, and less than or equal to 0.15.

The second loop coil and the third loop coil form a third overlapping sub-region, and the second loop coil and the fourth loop coil form a fourth sub-overlapping region.

A third ratio an area of the third overlapping sub-region to an area of the second loop coil or to the area of the third loop coil is greater than or equal to 0.08, and less than or equal to 0.15.

A fourth ratio of an area of the fourth overlapping sub-region to the area of the second loop coil or to an area of the fourth loop coil is greater than or equal to 0.08, and less than or equal to 0.15.

In one of the embodiments, the first loop coil and the third loop coil form a first overlap sub-region, and the first loop coil and the fourth loop coil form a second overlap sub-region; an area of the third loop coil is equal to an area of the fourth loop coil, and an area of the first overlap sub-region is equal to an area of the second overlap sub-region.

In one of the embodiments, the second loop coil and the third loop coil form a third overlap sub-region, and the second loop coil and the fourth loop coil form a fourth overlap sub-region, the area of the third loop coil is equal to the area of the fourth loop coil, and an area of the third overlap sub-region is equal to an area of the fourth overlap sub-region.

In one of the embodiments, the first overlap region is symmetrically arranged with respect to a symmetry axis, the first overlap sub-region and the second overlap sub-region are symmetrically arranged with respect to the symmetry axis, and the symmetry axis is parallel to the first direction.

In one of the embodiments, the first overlap region is symmetrically arranged with respect to the symmetry axis, the third overlap sub-region and the fourth overlap sub-region are symmetrically arranged with respect to the symmetry axis, and the symmetry axis is parallel to the first direction.

In one of the embodiments, each two adjacent coils in the second coil group overlap.

In one of the embodiments, in the second coil group, the at least two coils arranged in the second direction includes a third loop coil and a fourth loop coil. A second overlap region is formed between the third loop coil and the fourth loop coil. The second overlap region includes a first sub-region of second overlap region and a second sub-region of second overlap region, and the first sub-region of second overlap region and the second sub-region of second overlap region are both away from a center of area where the third loop coil and the fourth loop coil are arranged.

In one of the embodiments, the first overlap region of the first loop coil and the second loop coil is spaced apart from the third loop coil and the fourth loop coil in the second coil group. An area of the first loop coil is equal to an area of the second loop coil; an area of the third loop coil is equal to an area of the fourth loop coil; and an area of the first sub-region of second overlap region is equal to an area of the second sub-region of second overlap region.

In one of the embodiments, the first loop coil and the second loop coil are symmetrically arranged with respect to an axis parallel to the second direction, and the first loop coil is symmetrical with respect to the symmetry axis.

The third loop coil and the fourth loop coil are symmetrically arranged with respect to the symmetry axis, and the third loop coil is symmetrical with respect to the axis parallel to the second direction.

The first overlap region is symmetrically arranged with respect to the symmetry axis, and the symmetry axis is parallel to the first direction.

In one of the embodiments, an area of the third loop coil is equal to an area of the fourth loop coil. A third overlap region is formed between the first loop coil in the first coil group and the third loop coil in the second coil group; a fourth overlap region is formed between the first loop coil in the first coil group and the fourth loop coil in the second coil group; an area of the third overlap region and an area of the fourth overlap region are equal.

In one of the embodiments, an area of the third loop coil is equal to an area of the fourth loop coil. The second loop coil in the first coil group and the third loop coil in the second coil group form a fifth overlap region; the second loop coil in the first coil group and the fourth loop coil in the second coil group form a sixth overlap region; and an area of the fifth overlap region is equal to an area of the sixth overlap region.

In a second aspect, the present application further provides a coil assembly, used for a magnetic resonance device and including the magnetic resonance coil of the first aspect, a housing, and a substrate.

The substrate is a flexible substrate, and at least part of the magnetic resonance coil is printed on the substrate.

The substrate is arranged on the housing to allow the first direction of the magnetic resonance coil to be parallel to a length direction of the housing, wherein the length direction of the housing is a direction in which the to-be-scanned object is moved into a scanning cavity of the magnetic resonance device.

In one of the embodiments, a shape of the housing comprises any one of a cylindrical shape, a semi-cylindrical shape, and a flat plate shape, and the substrate is fixed on the housing The substrate is fixed on the housing.

In a third aspect, the present application provides a magnetic resonance device including the coil assembly of the second aspect.

For the magnetic resonance coil, the coil assembly and the magnetic resonance device above, the magnetic resonance coil is configured to receive the magnetic resonance signal of the to-be-scanned object. The magnetic resonance coil includes the first coil group and the second coil group. The first coil group includes at least two coils arranged in the first direction, and the second coil group includes at least two coils arranged in the second direction. Each two adjacent coils in the first coil group and the second coil group are arranged to be decoupled, thereby making the magnetic resonance signals received by the first coil group and the second coil group more accurate. The first coil group and the second coil group are arranged to overlap, thereby making the magnetic resonance signals received by the whole magnetic resonance coil more accurate. Since the magnetic resonance coil includes coil groups arranged in two directions respectively, the number of coil groups arranged in this way may be relatively large, accordingly more magnetic resonance signals of the to-be-scanned object are received, and the more the signals are received, the faster the magnetic resonance imaging rate is, that is, the efficiency of the magnetic resonance imaging may be improved. Further, since each two adjacent coils in the second direction in the second coil group have a first space, or each two adjacent coils overlap, the coils arranged in the second direction may be decoupled relatively easily, so that the magnetic resonance signals received by the magnetic resonance coil are more accurate, thereby improving the accuracy of the magnetic resonance imaging.

### BRIEF DESCRIPTION OF THE DRAWINGS

FIG. 1 is a schematic view showing a structure of a magnetic resonance coil according to an embodiment.

FIG. 2a-2c show schematic structural views of three types of optional first coil groups according to another embodiment.

FIG. 3a-3b show schematic structural views of two types of optional second coil groups according to another embodiment.

FIG. 4 is a schematic view showing a connection structure between a third loop coil and a fourth loop coil according to another embodiment.

FIG. 5 is a schematic view showing a structure of a magnetic resonance coil according to another embodiment.

FIG. 6a is a schematic view showing a structure of a third loop coil and a fourth loop coil in a second coil group according to another embodiment.

FIG. 6b is a schematic view showing a structure of the second coil group in the magnetic resonance coil according to another embodiment.

FIG. 7 is a schematic view showing a structure of a second coil group according to another embodiment.

FIG. 8 is a schematic view showing a structure of a magnetic resonance coil according to another embodiment.

FIG. 9 is a simplified schematic view showing a structure of a magnetic resonance coil according to another embodiment.

FIG. 10 is a schematic view showing a structure of a coil assembly according to an embodiment of the present application.

### DESCRIPTION OF REFERENCE NUMERALS

10. first coil group;
20. second coil group;
101. first loop coil; 1011. first overlap sub-region; 1012, second overlap sub-region;
102. second loop coil; 1021. third overlap sub-region; 1022. fourth overlap sub-region;
201. third loop coil;
202. fourth loop coil;
203. electronic component;
100. first overlap region;
200. second overlap region; 2001. first sub-region of second overlap region; 2002. second sub-region of second overlap region;
300. third overlap region;
400. fourth overlap region;
500. fifth overlap region;
600. sixth overlap region;
110. substrate;
120. housing.

### DETAILED DESCRIPTION OF THE EMBODIMENTS

In order to make the objectives, technical solutions, and advantages of the present application clearer and better understood, the present application is further described in detail hereinafter in conjunction with the accompanying drawings and embodiments. It should be understood that the specific embodiments described herein are only used to explain the present application but not intended to limit the present application.

In the description of the present application, it should be noted that the terms “center”, “up”, “down”, “left”, “right”, “vertical”, “horizontal”, “inside”, “outside”, etc., indicating orientations or position relationships, are based on the orientations or position relationships shown in the accompanying drawings and only used for convenience of describing the present application and simplifying the description, but do not indicate or imply that a device or an element referred to must have a specific orientation, be constructed and operated in a specific orientation, and therefore cannot be understood as a limitation on the present application. In addition, the terms “first”, “second”, and “third” are used for describing only but cannot be understood as indicating or implying relative importance. The terms “first position” and “second position” denote two different positions.

In the description of this application, it should be noted that, unless otherwise clearly specified and limited, the terms “install”, “connect”, and “communicate” should be understood in a broad sense, for example, may be a fixed connection or a detachable connection, may be a mechanical connection or an electrical connection, may be a direct connection or an indirect connection through an intermediate medium, or may be an internal communication of two components. For the ordinary skilled in the art, the specific meanings of the above terms in this application may be understood according to specific circumstances.

In the related art, when a magnetic resonance scanning is performed on the to-be-scanned object such as a human body or an animal body, the to-be-scanned object is mostly scanned in various directions by a magnetic resonance coil of a magnetic resonance device to obtain scanned magnetic resonance signals, and an image is reconstructed based on the scanned magnetic resonance signals, thus obtaining a reconstructed magnetic resonance image. However, in the related art, when scanning and imaging are performed on the to-be-scanned object, there is a problem of a low imaging efficiency. In view of this, the embodiments of the present application provide a magnetic resonance coil, a coil assembly, and a magnetic resonance device, which can solve the technical problem above.

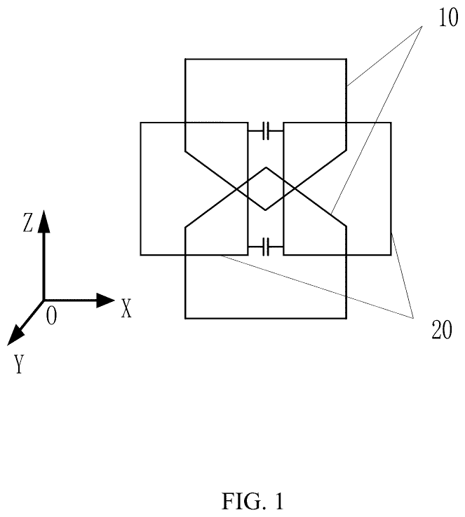

FIG. 1 is a schematic view showing a structure of a magnetic resonance coil according to an embodiment. Referring to FIG. 1, the magnetic resonance coil is configured to receive a magnetic resonance signal of a to-be-scanned object. The magnetic resonance coil includes a first coil group 10 and a second coil group 20. The first coil group 10 includes at least two coils arranged in a first direction (e.g., Z direction as shown in FIG. 1), and the second coil group 20 includes at least two coils arranged in a second direction (e.g., X direction as shown in FIG. 1). The first coil group 10 and the second coil group 20 are arranged to overlap, and each two adjacent coils in the first coil group 10 and the second coil group 20 are arranged to be decoupled. In an embodiment, the first direction Z is perpendicular to the second direction X. In an embodiment of the present application, each two adjacent coils in the second coil group 20 have a first space, that is each two adjacent coils do not overlap. Alternatively, a space may also be reserved between each two adjacent coils in the first coil group 10.

In this embodiment, the magnetic resonance coil is a receiving coil, which is configured to mainly receive the magnetic resonance signals of the to-be-scanned object during the magnetic resonance scanning of the to-be-scanned object. The to-be-scanned object may be an animal body, or may also be a human body. In an optional embodiment, the animal body may be a small-sized animal body, such as an experimental mouse, an experimental rabbit, etc. Of course, the animal body actually required may also be selected according to actual situations.

As shown in FIG. 1, in an embodiment of the present application, the first coil group 10 is arranged in the first direction Z, and the first coil group 10 may include two or more coils. In the first coil group 10, each two adjacent coils in the two or more coils may be arranged to overlap, or may be arranged to be spaced apart, or may be arranged in other manners. For the adjacent coils in the first coil group 10, the method of decoupling coils may include overlapping decoupling, or may be any other decoupling method, as long as decoupling the multiple coils can be achieved.

Coils in the first coil group 10 may have different shapes, for example, loop coils, planar coils, surface coils, etc. In the arrangement that the first coil group 10 includes multiple coils, the shapes of the coils may be the same, partially the same and partially different, or completely different.

A size or area of each coil in the first coil group 10 may be configured according to actual situations. In the arrangement that the first coil group 10 includes multiple coils, the sizes or areas of all coils may be equal or unequal.

Continuing to refer to FIG. 1, the second coil group 20 is arranged in the second direction X, and the second coil group 20 includes at least two coils, such as two or three coils. The coils in the second coil group 20 may be arranged in sequence along the second direction X, and each two adjacent coils have a space. In other words, each two adjacent coils do not overlap, and may overlap or not overlap at other regions or positions. In this way, the decoupling may be realized through the arrangement that each two adjacent coils do not overlap, but overlap or are arranged in other manners at other regions or positions, so that each two adjacent coils may be decoupled relatively easily, and that the magnetic resonance signals received by the second coil group 20 are more accurate.

In addition, the spaces each between every two adjacent coils in the second coil group 20 may be completely the same, or partially the same and partially different, or completely different.

Further, for the first direction Z and the second direction X, the first direction Z and second direction X may be perpendicular to each other. For example, the first direction Z may be the head-foot (HF) direction, and the second direction X may be the right-left (RL) direction. Exemplarily, the first direction Z may be set according to an actual magnetic resonance scanning scene. For example, when the to-be-scanned object lies on the back on the bed, the first direction Z may be a direction parallel to an axial direction of a scanning cavity of a magnetic resonance device. For another example, when the to-be-scanned object is standing, the first direction Z may be a direction parallel to the body of the to-be-scanned object in a vertical direction. For the second direction X, for example, when the to-be-scanned object lies on the stomach on the bed, the second direction X may be a direction perpendicular to the axial direction of the scanning cavity and a right-left (RL) direction parallel to the to-be-scanned object.

As for the arrangement of the first coil group 10 and the second coil group 20, the first coil group 10 and the second coil group 20 may be arranged in sequence in respective directions, or may be arranged in other manners. The first coil group 10 and the second coil group 20 are arranged to overlap with each other to decouple the coils. Specifically, the decoupling may be performed by making use of the area of the overlap region between the two coil groups. Of course, the decoupling may be performed by other methods, as long as the first coil group 10 and the second coil group 20 may be decoupled, so that the accuracy of the magnetic resonance signals received by the entire magnetic resonance coil may be improved.

The magnetic resonance coil is configured to receive the magnetic resonance signals of the to-be-scanned object. The magnetic resonance coil includes the first coil group 10 and the second coil group 20. The first coil group 10 includes at least two coils arranged in the first direction, and the second coil group 20 includes at least two coils arranged in the second direction. Each two adjacent coils in the first coil group 10 and the second coil group 20 are arranged to be decoupled, thereby making the magnetic resonance signals received by the first coil group 10 and the second coil group 20 more accurate. The first coil group 10 and the second coil group 20 are arranged to overlap, thereby making the magnetic resonance signals received by the whole magnetic resonance coil more accurate. Since the magnetic resonance coil includes coil groups arranged in two directions respectively, the number of coil groups arranged in this way may be relatively large, accordingly more magnetic resonance signals of the to-be-scanned object are received, and the more the signals are received, the faster the magnetic resonance imaging rate is, that is, the efficiency of the magnetic resonance imaging may be improved. Further, since each two adjacent coils in the second direction X have a space, the coils arranged in the second direction X may be decoupled relatively easily, so that the magnetic resonance signals received by the magnetic resonance coil are more accurate, thereby improving the accuracy of the magnetic resonance imaging.

The arrangement of the first coil group 10 and the second coil group 20 is briefly described in the above embodiment. The specific arrangement of the first coil group 10 and the second coil group 20 will be described in detail in the embodiments below.

Please continue to refer to FIG. 1, the first coil group 10 and the second coil group 20 are arranged to overlap along a third direction (e.g., Y direction as shown in FIG. 1), and the third direction Y is perpendicular to both the first direction Z and the second direction X.

Specifically, the first coil group 10 and the second coil group 20 may be arranged to overlap in the third direction Y, and the third direction Y may be, for example, the anterior posterior (AP) direction, which is perpendicular to both the first direction Z and the second direction X. For example, the third direction Y may be set according to the actual magnetic resonance scanning scene. For example, when the to-be-scanned object lies on the back on the bed, the third direction Y may be a direction perpendicular to the axial direction of the scanning cavity and perpendicular to the to-be-scanned object.

The area of the overlap region between the first coil group 10 and the second coil group 20 may also be specifically configured according to the conditions of the decoupling between the first coil group 10 and the second coil group 20. In the overlap region between the first coil group 10 and the second coil group 20, the currents flowing through the first coil group 10 and the second coil group 20 are just opposite, so the directions of the magnetic fields are also opposite, and the magnetic fields may offset against each other, thereby decoupling each two adjacent coils of the first coil group 10 and the second coil group 20 via overlapping.

In this embodiment, the first coil group 10 and the second coil group 20 are arranged along to overlap in the third direction Y, and the third direction Y is perpendicular to both the first direction Z and the second direction X. In this way, the two coils may be decoupled easily via overlapping, thereby ensuring the accuracy of the magnetic resonance signals finally received by the magnetic resonance coil.

Several types of coils in the first coil group 10 are described in the above embodiment, and one type of the coils will be described in the following embodiments by taking the first coil group 10 including two coils as an example.

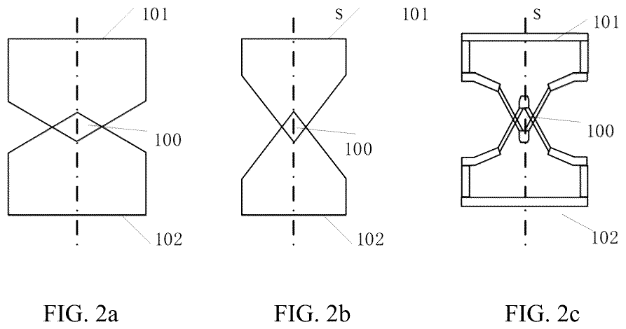

FIG. 2a-2c show schematic structural views of three types of optional first coil groups 10 according to another embodiment. As shown in FIG. 2a-2c, in the first coil group 10, the at least two coils arranged in the first direction Z includes a first loop coil 101 and a second loop coil 102. The first loop coil 101 and the second loop coil 102 have a first overlap region 100. Further, the first overlap region 100 is symmetrically arranged with respect to a symmetry axis S, and the symmetry axis S is parallel to the first direction Z.

As shown in FIG. 2a-2c, two loop coils are arranged adjacent to each other along the first direction Z, and are named the first loop coil 101 and the second loop coil 102 respectively. The first loop coil 101 and the second loop coil 102 have the same shape, the same size, and the same area. The first loop coil 101 and the second loop coil 102 overlap, are arranged along the first direction Z and disposed on the substrate 110 where the magnetic resonance coil is arranged. Three types of shapes of first loop coils 101 and second loop coils 102 shown in FIG. 2a-2c are only examples, and loop coils with other shapes may be configured according to actual conditions, for example, they are configured to have ring shapes, etc. In addition, the first loop coil 101 and the second loop coil 102 may be arranged on the same plane and overlap, and the overlap region therebetween may be named the first overlap region 100. The size of the first overlap region 100 is related to the decoupled amount between the first loop coil 101 and the second loop coil 102. Decoupling refers to removing electromagnetic interference between coils. In the first overlap region 100, the direction of the magnetic field generated by the first loop coil 101 and entering the second loop coil 102 is opposite to the direction of the magnetic field generated by the second loop coil 102 and entering the first loop coil 101, so that the magnetic fields in the first overlap region 100 generated by the first loop coil 101 and by the second loop coil 102 respectively may just offset against each other, thereby decoupling the first loop coil 101 and the second loop coil 102.

In addition, the first overlap region 100 is the overlap region of the first loop coil 101 and the second loop coil 102. The first overlap region 100 is symmetrical with respect to a symmetry axis S parallel to the first direction Z, so that the first overlap region 100 is evenly distributed on both sides of the symmetry axis S.

Further, in the related art, during magnetic resonance imaging by using a magnetic resonance coil, the signal-to-noise ratio of an imaging center region or a field of view center (FOV center) region is generally lower than the signal-to-noise ratio of other non-imaging center regions or non-FOV center regions. In the disclosure, the first overlap region 100 corresponds to an imaging region or a field of view (FOV) during a magnetic resonance imaging process. The center of the first overlap region 100 corresponds to an imaging center or a FOV center, and a neighborhood of the imaging center or of the FOV center is an imaging center region or a FOV center region. In order to improve the signal-to-noise ratio of the imaging center region or FOV center region, as an optional embodiment, the first overlap region 100 includes at least four angles, and the at least four angles are all oblique angles.

Referring to the first coil group 10 shown in FIG. 2a-2c, the first loop coil 101 and the second loop coil 102 have the first overlap region 100, and the first overlap region 100 has a quadrangular shape, which includes four inner angles. The four inner angles are all oblique angles, that is, they are not angles of 90 degrees. Such an arrangement ensures that the direction of the magnetic field generated by the first loop coil 101 and entering the second loop coil 102 and the direction of the magnetic field generated by the second loop coil 102 entering the first loop coil 101 are not perpendicular to the four sides of the first overlap region 100, thereby reducing the noise in the imaging center region or in the FOV center region, and improving the signal-to-noise ratio of the imaging center region or FOV center region.

In this embodiment, the first coil group 10 includes the first loop coil 101 and the second loop coil 102 which have the first overlap region 100, and the first overlap region 100 is symmetrically arranged with respect to the symmetry axis S. The symmetry axis S is parallel to the first direction Z, so that the two loop coils may be decoupled easily through the first overlap region 100. The coils arranged on both sides of the symmetry axis S can be decoupled through the symmetrical arrangement, thereby ensuring the decoupling effect of the entire first coil group 10.

Several types of coils in the second coil group 20 are described in the above embodiments, and one type of coils will be described in the following embodiments by taking the second coil group 20 including two coils as an example.

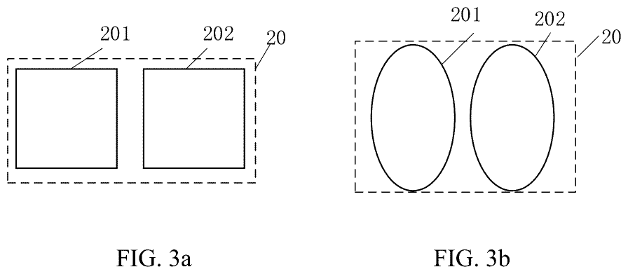

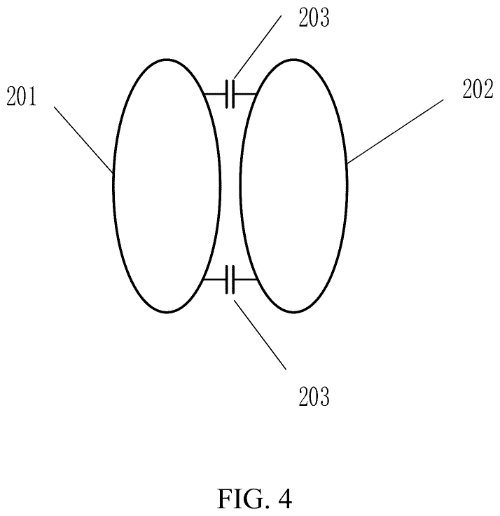

FIGS. 3a-3b show schematic structural views of two types of optional second coil groups 20 according to another embodiment. As shown in FIGS. 3a-3b, in an embodiment of the present application, in the second coil group 20, each two adjacent coils have a first space, that is, each two adjacent coils do not overlap. FIG. 4 is a schematic view showing a connection structure between a third loop coil and a fourth loop coil according to another embodiment, as shown in FIG. 4, in the second coil group 20, the at least two coils arranged in a second direction X includes a third loop coil 201 and a fourth loop coil 202, and the third loop coil 201 and the fourth loop coil 202 are connected by electronic components 203, and the electronic components 203 include capacitors. A current flowing from the third loop coil 201 to the fourth loop coil 202 through one electronic component 203 and a current flowing from the fourth loop coil 202 to the third loop coil 201 through another electronic component 203 are opposite in direction and equal in magnitude.

As shown in FIG. 3a-3b, the two loop coils in the second coil group 20 are adjacently arranged along the second direction X, and are named the third loop coil 201 and the fourth loop coil 202 respectively. The third loop coil 201 and the fourth loop coil 202 have the same shape and the same area. Generally, the shape of the third loop coil 201 and the shape of the fourth loop coil 202 are the same, such as a rectangle and a ring (such as a circular shape or an ellipse shape) shown in FIG. 3a-3b, or any other shape such as an irregular shape, etc.

In addition, the third loop coil 201 and the fourth loop coil 202 may be arranged on the same plane, and may be connected through the electronic component 203. As an optional embodiment, the electronic component 203 includes at least a capacitor, and alternatively, may include any other electronic component. The third loop coil 201 and the fourth loop coil 202 may be connected through one electronic component 203, and may also be connected through multiple electronic components 203.

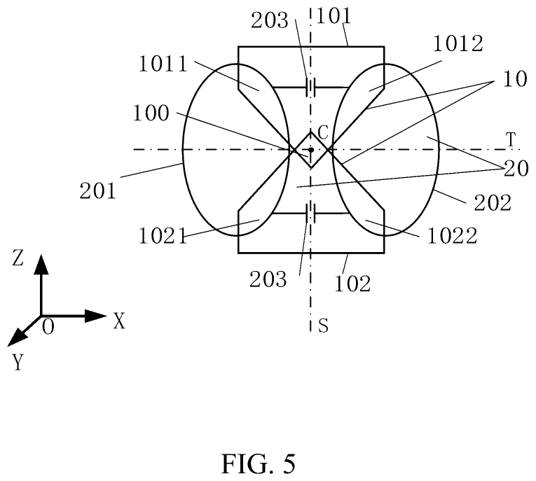

As an example, the third loop coil 201 and the fourth loop coil 202 are both circular-loop coils, and the third loop coil 201 and the fourth loop coil 202 are connected by two electronic components 203. Referring to FIG. 4, a schematic view showing a connection structure between the third loop coil 201 and the fourth loop coil 202, and referring to FIG. 5, a schematic view showing a structure of a magnetic resonance coil according to another embodiment, two sides the third loop coil 201 and the fourth loop coil 202, which are away from an imaging center, namely a center C of an area where the third loop coil 201 and the fourth loop coil 202 are arranged, may be connected by electronic components 203 respectively, such as the capacitors shown in the figures.

After the third loop coil 201 and the fourth loop coil 202 are connected by the electronic components 203, based on the Hough's law of current, for the third loop coil 201 and the fourth loop coil 202 connected by the electronic components 203, it is known that the current flowing from the third loop coil 201 to the fourth loop coil 202 through one electronic component 203 and the current flowing from the fourth loop coil 202 to the third loop coil 201 through another electronic component 203 are opposite in direction and equal in magnitude, and the two currents offset against each other, that is, the magnetic fields generated by the two currents may offset against each other, thereby decoupling the third loop coil 201 and the fourth loop coil 202.

In this embodiment, the second coil group 20 includes the third loop coil 201 and the fourth loop coil 202, which are connected by the electronic components 203, and the currents flowing from the two loop coils to each other through the electronic components 203 are opposite in direction and equal in magnitude. In this way, through the connection of the electronic components 203, the two loop coils may be decoupled more easily, thereby reducing the cost of decoupling. Moreover, a space is also reserved between the two loop coils, so that the magnetic resonance signals and at the edge may be better analyzed, thereby further improving the efficiency of the magnetic resonance imaging. In addition, the electronic components 203 connecting the third loop coil 201 and the fourth loop coil 202 include at least a capacitor, so that the capacitor, may reduce the difficulty in decoupling the two loop coils, and may also reduce the cost of decoupling.

In an embodiment of the present application, as shown in FIG. 2a-2c, the at least two coils arranged in the first direction in the first coil group 10 includes the first loop coil 101 and the second loop coil 102, and the first loop coil 101 and the second loop coil 102 have the first overlap region 100. As shown in FIG. 3a-3b and FIG. 4, two loop coils in the second coil group 20 are adjacently arranged along the second direction X and named the third loop coil 201 and the fourth loop coil 202 respectively. FIG. 5 is a schematic view showing a structure of a magnetic resonance coil according to another embodiment, as shown in FIG. 5, The first overlap region 100 of the first loop coil 101 and the second loop coil 102 is spaced apart from the third loop coil 201 and the fourth loop coil 202 in the second coil group 20, that is, the first overlap region 100 overlaps with neither the third loop coil 201 nor the fourth loop coil 202 in the second coil group 20. In an embodiment, as shown in FIG. 5, the first loop coil 101 and the third loop coil 201 form a first overlap sub-region 1011, the first loop coil 101 and the fourth loop coil 202 form a second overlap sub-region 1012, the area of the third loop coil 201 is equal to the area of the fourth loop coil 202, and the area of the first overlap sub-region 1011 is equal to the area of the second overlap sub-region 1012. Such arrangements can avoid a loss of magnetic resonance signals due to changes in FOVs during an imaging process, which are caused by changes in areas of corresponding overlapping regions.

In an embodiment of the present application, as shown in FIG. 5, the first loop coil 101 and the third loop coil 201 form the first overlap sub-region 1011, and the first loop coil 101 and the fourth loop coil 202 form the second overlap sub-region 1012. A first ratio of the area of the first overlapping sub-region 1011 to the area of the first loop coil 101 or to the area of the third loop coil 201 is greater than or equal to 0.08, and less than or equal to 0.15. A second ratio of the area of the second overlapping sub-region 1012 to the area of the first loop coil 101 or the area of the fourth loop coil 202 is greater than or equal to 0.08, and less than or equal to 0.15. The second loop coil 102 and the third loop coil 201 form a third overlapping sub-region 1021, and the second loop coil 102 and the fourth loop coil 202 form a fourth overlapping sub-region 1022. A third ratio of the area of the third overlapping sub-region 1021 to the area of the second loop coil 102 or to the area of the third loop coil 201 is greater than or equal to 0.08, and less than or equal to 0.15. A fourth ratio of the area of the fourth overlapping sub-region 1022 to the area of the second loop coil 102 or to the area of the fourth loop coil 202 is greater than or equal to 0.08, and less than or equal to 0.15. Based on a lot of research and experiments, it is learned that if the first ratio, the second ratio, the third ratio or the fourth ratio is less than 0.08, a corresponding overlapping region between corresponding overlapped coils is too small, the overlapped coils are decoupled slightly, and the magnetic resonance signals received by the first coil group 10 and the second coil group 20 arranged in two directions are weakened, thus reducing the accuracy of magnetic resonance imaging is reduced. If the first ratio, the second ratio, the third ratio and the fourth ratio are greater than 0.15, a corresponding overlapping region between corresponding overlapped coils is too large, the overlapped coils are decoupled heavily, and the magnetic resonance signals received by the first coil group 10 and the second coil group 20 arranged in two directions will interfere with each other, thus also reducing the accuracy of magnetic resonance imaging.

In an embodiment of the present application, as shown in FIG. 5, the first overlap region 100 is symmetrically arranged with respect to a symmetry axis S, and the first overlap sub-region 1011 and the second overlap sub-region 1012 are symmetrically arranged with respect to the symmetry axis S. The symmetry axis S is parallel to the first direction Z.

In an embodiment of the present application, as shown in FIG. 5, the second loop coil 102 and the third loop coil 201 form a third overlap sub-region 1021, and the second loop coil 102 and the fourth loop coil 202 form a fourth overlap sub-region 1022. The area of the third overlap sub-region 1021 is equal to the area of the fourth overlap sub-region 1022.

Further, in an embodiment, the first overlap region 100 is symmetrically arranged with respect to the symmetry axis S, and the third overlap sub-region 1021 and the fourth overlap sub-region 1022 are symmetrically arranged with respect to the symmetry axis S. The symmetry axis S is parallel to the first direction Z. Further, the first loop coil 101 and the second loop coil 102 are symmetrically arranged with respect to an axis T parallel to the second direction X, and the first loop coil 101 is symmetrical with respect to the symmetry axis S. The third loop coil 201 and the fourth loop coil 202 are symmetrically arranged with respect to the symmetry axis S, and the third loop coil 201 is symmetrical with respect to the axis T parallel to the second direction X. The first overlap area 100 is symmetrically arranged with respect to the symmetry axis S, and the symmetry axis S is parallel to the first direction Z.

The above embodiment illustrates the implementation manner by which the two coils in the second coil group 20 may be decoupled by the connected electronic components 203. The implementation manners by which the two coils in the second coil group 20 may be decoupled via overlapping will be described in the following embodiments.

In another embodiment of the present application, the magnetic resonance coil includes the first coil group 10 arranged in the first direction Z, and the second coil group 20. The second coil group 20 includes at least two coils arranged in the second direction X, and each two adjacent coils overlap. In this way, the coils arranged in the second direction X may be decoupled relatively easily, so that the magnetic resonance signals received by the magnetic resonance coil are more accurate, thereby improving the accuracy of the magnetic resonance imaging.

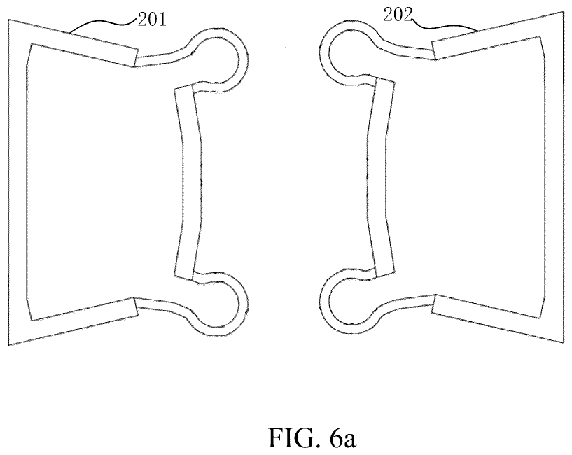

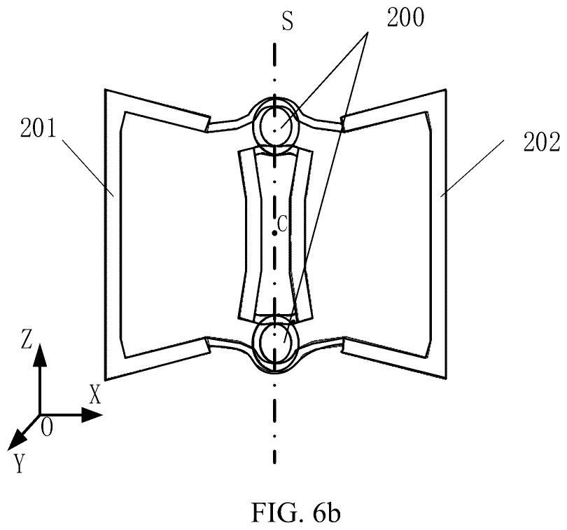

FIG. 6a is a schematic view showing a structure of a third loop coil and a fourth loop coil in a second coil group according to another embodiment, and FIG. 6b is a schematic view showing a structure of the second coil group 20 in a magnetic resonance coil according to another embodiment. Referring to FIG. 6a and FIG. 6b, the at least two coils arranged in the second direction X in the second coil group 20 includes the third loop coil 201 and the fourth loop coil 202. A second overlap region 200 is formed between the third loop coil 201 and the fourth loop coil 202. Further, the second overlap region 200 is symmetrically arranged with respect to the symmetry axis S, and the symmetry axis S is parallel to the first direction Z.

Referring to FIG. 6b, two loop coils in the second coil group 20 are adjacently arranged along the second direction X, and are named the third loop coil 201 and the fourth loop coil 202 respectively. The third loop coil 201 and the fourth loop coil 202 have the same shape and the same area. In addition, the third loop coil 201 and the fourth loop coil 202 may be arranged on the same plane, and may overlap, and the overlap therebetween may be named the second overlap region 200. The size of the second overlap region 200 is related to the decoupled amount between the third loop coil 201 and the fourth loop coil 202. In the second overlap region 200, the direction of the magnetic field generated by the third loop coil 201 and entering the fourth loop coil 202 and the direction of the magnetic field generated by the fourth loop coil 202 and entering the third loop coil 201 are opposite, so that the magnetic fields in the second overlap region 200 generated by the third loop coil 201 and the fourth loop coil 202 may offset against each other, thereby decoupling the third loop coil 201 and the fourth loop coil 202.

In addition, the second overlap region 200 is the overlap region of the third loop coil 201 and the fourth loop coil 202. The second overlap region 200 is symmetrical with respect to the symmetry axis S parallel to the first direction Z, so that the second overlap region 200 is evenly distributed on both sides of the symmetry axis S, thereby decoupling the coils on both sides of the symmetry axis.

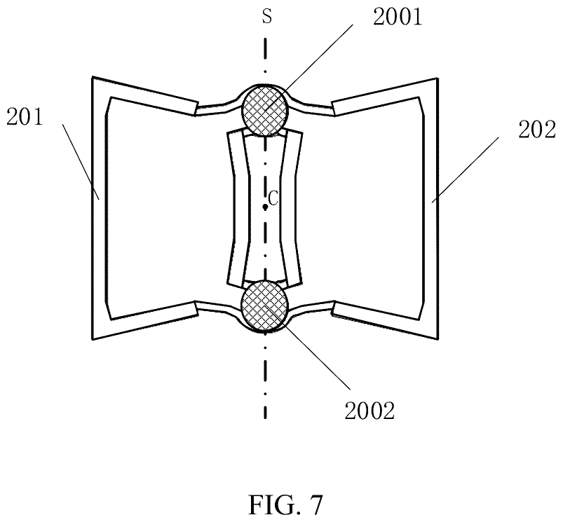

Further, in order to prevent the signal-to-noise ratio of the imaging region from being affected, two overlap regions may be configured for the third loop coil 201 and the fourth loop coil 202. That is to say, in an optional embodiment, referring to FIG. 7, a schematic view showing a structure of the second coil group 20 according to another embodiment, the second overlap region 200 includes a first sub-region of second overlap region 2001 and a second sub-region of second overlap region 2002, and the first sub-region of second overlap region 2001 and the second sub-region of second overlap region 2002 are both away from the imaging center, namely the center C of the area where the third loop coil and the fourth loop coil are arranged. That is, the first sub-region of second overlap region 2001 and the second sub-region of second overlap region 2002 are arranged away from the imaging center between two loop coils, so that the signal-to-noise ratio of the imaging center region may be guaranteed.

In this embodiment, the second coil group 20 includes the third loop coil 201 and the fourth loop coil 202 which have the second overlap region 200 therebetween. The second overlap region 200 is symmetrically arranged with respect to the symmetry axis S, and the symmetry axis S is parallel to the first direction Z, so that the two loop coils may be decoupled easily through the second overlap region 200, and that the coils on two sides of the symmetry axis S may be decoupled through the symmetrical arrangement, thereby ensuring the decoupling effect of the entire second coil group 20. Further, the second overlap region 200 includes two overlap regions with the same area and away from the imaging center, so that the third loop coil 201 and the fourth loop coil 202 may be decoupled more accurately, thereby improving the accuracy of the signals received between the third loop coil 201 and the fourth loop coil 202, improving the signal-to-noise ratio of the imaging center region, and improving the accuracy of the magnetic resonance imaging.

It is described in above embodiments that the first coil group 10 and the second coil group 20 also need to be decoupled. How to decouple the first coil group 10 including two loop coils and the second coil group 20 including two loop coils is described in the following embodiments.

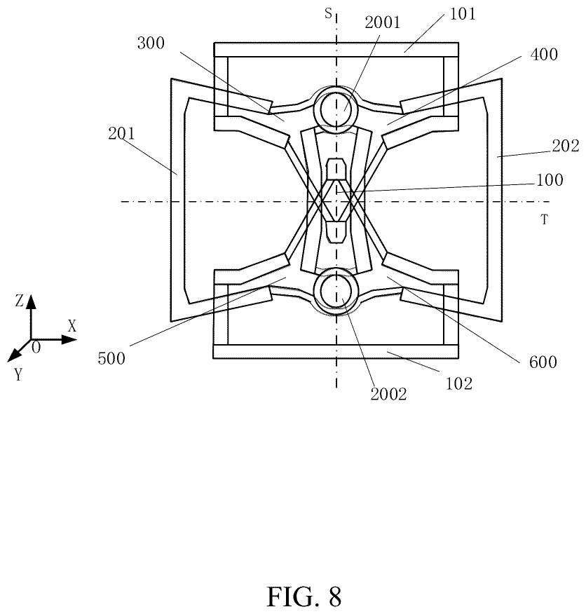

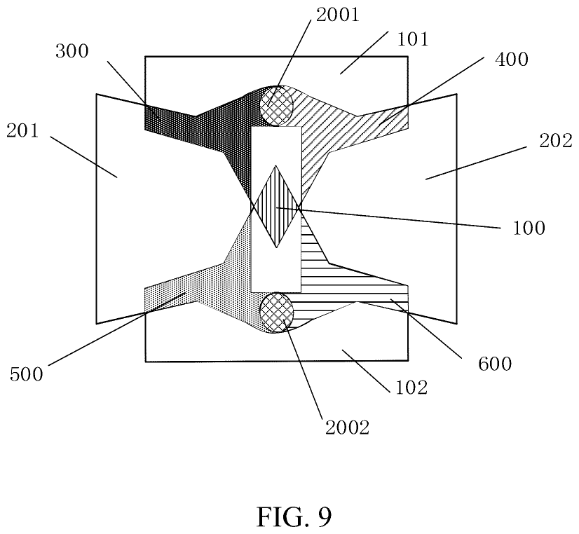

FIG. 8 is a schematic view showing a structure of a magnetic resonance coil provided based on the second coil group 20 shown in FIG. 6b and FIG. 7 according to another embodiment, and FIG. 9 is a simplified schematic view showing a structure of a magnetic resonance coil according to another embodiment. Referring to FIG. 8 and FIG. 9, the area of the third loop coil 201 is equal to the area of the fourth loop coil 202, the first loop coil 101 and the third loop coil 201 form a third overlap region 300, and the first loop coil 101 and the fourth loop coil 202 form a fourth overlap region 400, and the area of the third overlap region 300 is equal to the area of the fourth overlap region 400.

The third overlap region 300 is formed between the first loop coil 101 and the third loop coil 201, and the fourth overlap region 400 is formed between the first loop coil 101 and the fourth loop coil 202. The area of the third overlap region 300 and the area of the fourth overlap region 400 are equal, thus it may be ensured that the magnetic field passing through the third overlap region 300 between the first loop coil 101 and the third loop coil 201 and the magnetic field passing through the fourth overlap region 400 between the first loop coil 101 and the fourth loop coil 202 are equal in magnitude and opposite in direction, and the magnetic fields passing through these two overlap regions offset against each other, thereby decoupling the first loop coil 101 and the third loop coil 201, and decoupling the first loop coil 101 and the fourth loop coil 202.

In an embodiment, the area of the third loop coil 201 is equal to the area of the fourth loop coil 202. For the second loop coil 102, the second loop coil 102 and the third loop coil 201 form a fifth overlap region 500, and the second loop coil 102 and the fourth loop coil 202 form a sixth overlap region 600, and the area of the fifth overlap region 500 is equal to the area of the sixth overlap region 600.

The fifth overlap region 500 is formed between the second loop coil 102 and the third loop coil 201, and the sixth overlap region 600 is formed between the second loop coil 102 and the fourth loop coil 202. The area of the fifth overlap region 500 and the area of the sixth overlap region 600 are equal, thus it may be ensured that the magnetic field passing through the fifth overlap region 500 between the second loop coil 102 and the third loop coil 201 and the magnetic field passing through the sixth overlap region 600 between the second loop coil 102 and the fourth loop coil 202 are equal in magnitude and opposite in direction, and the magnetic fields passing through the two overlap regions offset against each other, thereby decoupling the second loop coil 102 and the third loop coil 201, and decoupling the second loop coil 102 and the fourth loop coil 202.

In this embodiment, the area of the overlap region between the first loop coil 101 and the third loop coil 201 and the area of the overlap region between the first loop coil 101 and the fourth loop coil 202 are equal, so that the first loop coil 101 and the third loop coil 201, and the first loop coil 101 and the fourth loop coil 202 may be decoupled more accurately, thereby improving the accuracy of the signals received between the first loop coil 101 and the third loop coil 201, and between the first loop coil 101 and the fourth loop coil 202. Moreover, the area of the overlap region between the second loop coil 102 and the third loop coil 201 and the area of the overlap region between the third loop coil 201 and the fourth loop coil 202 are equal, so that the decoupling between the second loop coil 102 and the third 201 and the decoupling between the second loop coil 102 and the fourth loop coil 202 may be achieved more accurately, thereby improving the accuracy of the signals received between the second loop coil 102 and the third loop coil 201 and received between the second loop coil 102 and the fourth loop coil 202.

In an embodiment of the present application, the first loop coil 101 and the second loop coil 102 in the first coil group 10 overlap with each other to form the first overlap region 100. The third loop coil 201 and the fourth loop coil 202 in the second coil group 20 overlap with each other to form the second overlap region 200, and the second overlap region 200 includes the first sub-region of second overlap region 2001 and the second sub-region of second overlap region 2002. Specifically, the first overlap region 100, and the first sub-region of second overlap region 2001 and the second sub-region of second overlap region 2002 in the second overlap region 200, are spaced apart from each other. In an embodiment of the present application, the area of the first loop coil 101 is equal to the area of the second loop coil 102, the area of the third loop coil 201 is equal to the area of the fourth loop coil 202, and the area of the first sub-region of second overlap region 2001 is equal to the area of the second sub-region of second overlap region 2002.

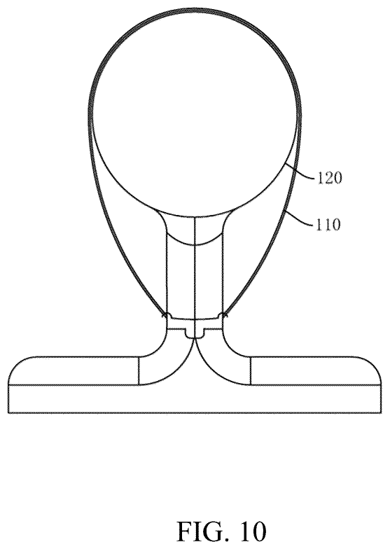

Based on the same inventive concepts, the embodiment of the present application further provides a coil assembly, and the coil assembly is used for a magnetic resonance device. FIG. 10 is a schematic view showing a structure of a coil assembly according to an embodiment of the present application. As shown in FIG. 10, the coil assembly includes the magnetic resonance coil of any one of the above embodiments, and also includes a housing 120 and a substrate 110. The substrate 110 is a flexible substrate. At least part of the magnetic resonance coil is printed on the substrate 110, and the substrate 110 is arranged on the housing 120, to allow the first direction of the magnetic resonance coil to be parallel to a length direction of the housing 120, and the length direction of the housing 120 is a direction in which the to-be-scanned object is moved into a scanning cavity of the magnetic resonance device.

As an optional embodiment, the shape of the housing 120 may be any one of a cylindrical shape, a semi-cylindrical shape, and a flat plate shape, and the substrate 110 is fixed on the housing. Corresponding to the housing 120 with the cylindrical shape or the semi-cylindrical shape, areas of loop coils described above are the areas of the loop coils that are expanded into a state of being flat.

The housing 120 and the to-be-scanned object may be both fixed on the bed. When the to-be-scanned object is scanned by using the magnetic resonance coil arranged on the housing 120, the housing 120 may cover a to-be-scanned part of the to-be-scanned object by adjusting a position of the to-be-scanned object relative to the housing 120.

The to-be-scanned object herein may be a human body or an animal body, and the to-be-scanned part may be the head, or the chest of the to-be-scanned object, etc. The first loop coil 101, the second loop coil 102, the third loop coil 201, and the fourth loop coil 202 in the magnetic resonance coil may be completely or partially printed on the flexible substrate 110, and the flexible substrate 110 is arranged on the housing 120 by gluing or the like, so as to obtain the coil assembly for scanning the to-be-scanned object.

By configuring the housings 120 to have different shapes, needs of different scanning scenes may be met. By arranging different coil assemblies, the magnetic resonance coil arranged on the housing 120 may be fixed on the to-be-scanned part of the to-be-scanned object through the housing 120 during subsequent scans, thereby preventing the received signals from being affected by a movement of the to-be-scanned part of the to-be-scanned object, improving the accuracy and effectiveness of the received signals, and ensuring the accuracy of subsequent imaging.

In this embodiment, the coil assembly includes the magnetic resonance coil, and the magnetic resonance coil is configured to receive the magnetic resonance signals of the to-be-scanned object. The magnetic resonance coil includes the first coil group 10 arranged in the first direction Z, and the second coil group 20 arranged in the second direction X. The second coil group 20 includes at least two coils, and each two adjacent coils in the second coil group 20 have a space, or each two adjacent coils overlap. The magnetic resonance coil includes the coil groups arranged in two directions, and the number of coil groups arranged in this way is relatively large, so more magnetic resonance signals of the scanned object are received. The more the signals are received, the faster the rate of the corresponding magnetic resonance imaging is, that is, the efficiency of magnetic resonance imaging may be improved. Moreover, since each two adjacent coils in the second direction X have a space, the coils arranged in the second direction X may be decoupled easily, so that the magnetic resonance signals received by the magnetic resonance coil are more accurate, thereby improving the accuracy of magnetic resonance imaging.

Based on the same inventive concepts, the embodiment of the present application further provides a magnetic resonance device, including the coil assembly above. The magnetic resonance device may also include other components.

In this embodiment, the magnetic resonance device includes the coil assembly, and the coil assembly includes a magnetic resonance coil. The magnetic resonance coil is configured to receive the magnetic resonance signals of the to-be-scanned object. The magnetic resonance coil includes the first coil group 10 arranged in the first direction Z, and the second coil group 20 arranged in the second direction X. The second coil group 20 includes at least two coils, and each two adjacent coils in the second coil group 20 have a first space, or each two adjacent coils overlap. Since the magnetic resonance coil includes coil groups arranged in two directions, and the number of coil groups arranged in this way is relatively large, more magnetic resonance signals of the scanned object are received. The more the signals are received, the faster the rate of the corresponding magnetic resonance imaging is, that is, the efficiency of magnetic resonance imaging may be improved. Moreover, each two adjacent coils in the second direction X have a space, the coils arranged in the second direction X may be decoupled easily, so that the magnetic resonance signals received by the magnetic resonance coil are more accurate, thereby improving the accuracy of magnetic resonance imaging.

The technical features of the above embodiments may be arbitrarily combined. To make the description concise, not all possible combinations of the technical features in the above embodiments are described. However, as long as there is no contradiction in the combinations of these technical features, all these combinations should be considered to be within the scope of this specification.

The embodiments above are only several implementation methods of the present application, and the descriptions thereof are relatively specific and detailed, but cannot be understood as limitations on the scope of the present application. It should be noted that, for the ordinary skilled in the art, various variations and improvements may be made without departing from the concepts of the present application, and these variations and improvements all belong to the protection scope of the present application. Therefore, the protection scope of the present application shall be subject to the appended claims.

What is claimed is:

1. A magnetic resonance coil for receiving a magnetic resonance signal of a to-be-scanned object, comprising:
a first coil group comprising at least two coils arranged in a first direction; and
a second coil group comprising at least two coils arranged in a second direction;
wherein the first coil group and the second coil group are arranged to overlap, and each two adjacent coils in the first coil group and in the second coil group are arranged to be decoupled.

2. The magnetic resonance coil of claim 1, wherein the first direction is perpendicular to the second direction.

3. The magnetic resonance coil of claim 1, wherein the first coil group and the second coil group are arranged to overlap in a third direction, and the third direction is perpendicular to both the first direction and the second direction.

4. The magnetic resonance coil of claim 1, wherein in the first coil group, the at least two coils arranged in the first direction comprises a first loop coil and a second loop coil; the first loop coil and the second loop coil have a first overlap region.

5. The magnetic resonance coil of claim 4, wherein each two adjacent coils in the second coil group have a first space.

6. The magnetic resonance coil of claim 5, wherein in the second coil group, the at least two coils arranged in the second direction comprises a third loop coil and a fourth loop coil, and the third loop coil and the fourth loop coil are connected by an electronic component, and the electronic component comprises a capacitor.

7. The magnetic resonance coil of claim 6, wherein the first overlap region of the first loop coil and the second loop coil is spaced apart from the third loop coil and the fourth loop coil in the second coil group.

8. The magnetic resonance coil of claim 7, wherein
the first loop coil and the third loop coil form a first overlap sub-region, and the first loop coil and the fourth loop coil form a second overlap sub-region;
a first ratio of an area of the first overlapping sub-region to an area of the first loop coil or to an area of the third loop coil is greater than or equal to 0.08, and less than or equal to 0.15;
a second ratio of an area of the second overlapping sub-region to the area of the first loop coil or an area of the fourth loop coil is greater than or equal to 0.08, and less than or equal to 0.15;
the second loop coil and the third loop coil form a third overlapping sub-region, and the second loop coil and the fourth loop coil form a fourth sub-overlapping region;
a third ratio an area of the third overlapping sub-region to an area of the second loop coil or to the area of the third loop coil is greater than or equal to 0.08, and less than or equal to 0.15; and
a fourth ratio of an area of the fourth overlapping sub-region to the area of the second loop coil or to an area of the fourth loop coil is greater than or equal to 0.08, and less than or equal to 0.15.

9. The magnetic resonance coil of claim 7, wherein the first loop coil and the third loop coil form a first overlap sub-region, and the first loop coil and the fourth loop coil form a second overlap sub-region; an area of the third loop coil is equal to an area of the fourth loop coil, and an area of the first overlap sub-region is equal to an area of the second overlap sub-region; or
the second loop coil and the third loop coil form a third overlap sub-region, and the second loop coil and the fourth loop coil form a fourth overlap sub-region; the area of the third loop coil is equal to the area of the fourth loop coil, and an area of the third overlap sub-region is equal to an area of the fourth overlap sub-region.

10. The magnetic resonance coil of claim 9, wherein the first overlap region is symmetrically arranged with respect to a symmetry axis; the first overlap sub-region and the second overlap sub-region are symmetrically arranged with respect to the symmetry axis; and the symmetry axis is parallel to the first direction.

11. The magnetic resonance coil of claim 9, wherein the first overlap region is symmetrically arranged with respect to the symmetry axis; the third overlap sub-region and the fourth overlap sub-region are symmetrically arranged with respect to the symmetry axis; and the symmetry axis is parallel to the first direction.

12. The magnetic resonance coil of claim 4, wherein each two adjacent coils in the second coil group overlap.

13. The magnetic resonance coil of claim 12, wherein in the second coil group, the at least two coils arranged in the second direction comprises a third loop coil and a fourth loop coil; and a second overlap region is formed between the third loop coil and the fourth loop coil; and
the second overlap region comprises a first sub-region of second overlap region and a second sub-region of second overlap region; and the first sub-region of second overlap region and the second sub-region of second overlap region are both away from a center of an area where the third loop coil and the fourth loop coil are arranged.

14. The magnetic resonance coil of claim 12, wherein the first overlap region of the first loop coil and the second loop coil is spaced apart from the third loop coil and the fourth loop coil in the second coil group.

15. The magnetic resonance coil of claim 13, wherein an area of the first loop coil is equal to an area of the second loop coil; an area of the third loop coil is equal to an area of the fourth loop coil; and an area of the first sub-region of second overlap region is equal to an area of the second sub-region of second overlap region.

16. The magnetic resonance coil of claim 13, wherein the first loop coil and the second loop coil are symmetrically arranged with respect to an axis parallel to the second direction, and the first loop coil is symmetrical with respect to a symmetry axis;
the third loop coil and the fourth loop coil are symmetrically arranged with respect to the symmetry axis, and the third loop coil is symmetrical with respect to the axis parallel to the second direction; and
the first overlap region is symmetrically arranged with respect to the symmetry axis; and the symmetry axis is parallel to the first direction.

17. The magnetic resonance coil of claim 13, wherein
an area of the third loop coil is equal to an area of the fourth loop coil; a third overlap region is formed between the first loop coil in the first coil group and the third loop coil in the second coil group; a fourth overlap region is formed between the first loop coil in the first coil group and the fourth loop coil in the second coil group; an area of the third overlap region and an area of the fourth overlap region are equal; or an area of the third loop coil is equal to an area of the fourth loop coil; the second loop coil in the first coil group and the third loop coil in the second coil group form a fifth overlap region; the second loop coil in the first coil group and the fourth loop coil in the second coil group form a sixth overlap region; and an area of the fifth overlap region is equal to an area of the sixth overlap region.

18. A coil assembly, used for a magnetic resonance device and comprising the magnetic resonance coil of claim 1, a housing, and a substrate, wherein
the substrate is a flexible substrate, and at least part of the magnetic resonance coil is printed on the substrate; and
the substrate is arranged on the housing to allow the first direction of the magnetic resonance coil to be parallel to a length direction of the housing, wherein the length direction of the housing is a direction in which the to-be-scanned object is moved into a scanning cavity of the magnetic resonance device.

19. The coil assembly of claim 18, wherein a shape of the housing comprises any one of a cylindrical shape, a semi-cylindrical shape, and a flat plate shape, and the substrate is fixed on the housing.

20. A magnetic resonance device, comprising the coil assembly of claim 18.
